(19) United States
(12) Patent Application Publication
(10) Pub. No.: US 2024/0168069 A1
(43) Pub. Date: May 23, 2024

(54) RECEIVER INTEGRATED REAL-TIME SPECTRUM ANALYSZER

(71) Applicant: Sound Devices LLC, Reedsburg, WI (US)

(72) Inventors: Matthew G. Anderson, Madison, WI (US); James Gordon, Crowborough, East Sussex (GB)

(73) Assignee: Sound Devices LLC, Reedsburg, WI (US)

(21) Appl. No.: 18/508,383

(22) Filed: Nov. 14, 2023

Related U.S. Application Data
(60) Provisional application No. 63/384,122, filed on Nov. 17, 2022.

(51) Int. Cl. G01R 23/18; H04R 1/22

(52) U.S. Cl. CPC G01R 23/18; H04R 1/222; H04R 2420/07

(57) ABSTRACT

Methods and devices are provided for a live real time spectrum analyzer to run on a wireless microphone receiver system whereby color coding, distinctive plotting and labelling may be applied to allow users to differentiate the source of RF emissions contributing to observed peaks in the spectrum.

### CROSS-REFERENCE TO RELATED APPLICATION

The present application claims priority of U.S. Provisional Patent Application No. 63/384,122, filed Nov. 17, 2022, the content of which is incorporated herein by reference in its entirety.

### FIELD OF THE INVENTION

The disclosed invention provides means to improve the ease and reliability associated with configuring a wireless microphone system. It does so by providing a real time spectrum analyzer (RTSA) on a receiver or receiver module. It also provides a graphical visual aid to assist users in identifying and establishing a unique frequency band for connections between wireless microphone transmitting and receiving unit pairs.

### BACKGROUND

Wireless microphone systems are becoming increasingly popular due to the convenience and flexibility offered by cordless operation. They allow performers additional freedom for active movement while engaged in performances on stage. In order to operate, these systems must maintain a wireless link for data communication between each wireless microphone transmitter and an assigned (paired) receiver. The wireless microphone transmitters are often placed in close proximity with the microphones themselves and in some cases are carried by or directly attached to performers while on stage. In contrast, wireless microphone receivers are often located at a stationary location closer to a sound equipment cart or desk where a sound expert (henceforth referred to as a “user”) works to operate a microphone mixer/recorder system for recording, mixing, broadcast and/or playback. The collection of these wireless microphones along with their respective transmitter and receiver pairs, mixer unit, recording unit (if present) and other supporting equipment that may be stationed at or in the vicinity of an equipment cart and stage are referred to as a “wireless microphone environment”. Sound bags holding receivers and mixer recorders are often used in the field production.

When configuring a wireless microphone environment, the user must often assign various wireless microphone transmitter and receiver pairs to operate in specific frequency bands. This type of operation is called frequency division multiplexing. When a user configures a particular wireless microphone receiver (and the corresponding paired wireless transmitter) that particular receiver unit is referred to as the “receiver transmitter pair under configuration” or more simply as an “RTPUC”. In order to use and configure these in an optimal fashion, a user often times will set details on configuration such as assigning a frequency band for each wireless microphone transmitter/receiver pair. In order to transmit audio data over an RF link, multiple types of modulation may be utilized, depending on the environment, physical limitations for power output (batteries) and government regulations that limit available broadcast frequencies, power and bandwidth. In some embodiments, phase shift keying (PSK) may be preferred. Other types of modulation may include quadrature phase shift keying (QPSK), frequency modulation (FM, frequency shift keying (FSK) or amplitude shift keying (ASK). Ideally, however, to maximize performance, a unique frequency band (that is not otherwise heavily used) should be allocated to each pair, as having shared bands between two or more wireless microphone transmitter and receiver pairs along with any other wireless may cause interference with wireless microphone RF signals and cause a reduction in wireless microphone data rate and reliability—leading to potential difficulties in using the wireless microphone environment that may include reduced range, noise and dropouts between microphone transmitter and receiver pairs.

Previous attempts to mitigate RF signal interference have included the use of a real-time spectrum analyzer (RSTA) which is a relatively expensive piece of equipment. A multi-coupler can be used to feed the signal from the receiver antenna to the RTSA and the RTSA dynamically shows a trace of amplitude versus frequency on its display screen. The trace updates several times per second, and gives the user a real time visual indication of any transmitters being received by the receiver antenna as well as other interference on the antenna. An RTSA allows the user to identify bands where relatively low levels of RF interference are likely to exist, but its use requires that the user own, carry and attach the needed equipment. In order to avoid the need for an RTSA, some receivers include a frequency scan feature in which antenna signals are measured as the frequency is slowly scanned. The receiver displays an updated graph for the RF power levels (often with dBm power levels displayed vertically along the y-axis) as a function of frequency (horizontally spanning the x-axis), for the total RF levels present for all nearby devices (including all wireless microphone transmitter and receiver pairs and any other equipment emitting RF signals in the vicinity). The plot representing the RF power spectrum is displayed and updated over time or when requested (refreshed once every several seconds or more). Such frequency scans do not enable the user to see the dynamic movement of the RF power spectrum in real time like an RTSA, which is a drawback of the typical scan feature. For example, it is helpful to identify the temporal behavior of a given transmitter, e.g., determining whether the signal is consistent in real time, and the typical receiver scan feature does not provide adequate information to do so.

### SUMMARY

In one aspect, the invention is directed to the incorporation of a real-time spectrum analyzer (RTSA) into a receiver or receiver module. FIGS. 5A and B shows an exemplary circuit that enables the practical implementation of an RTSA into a receiver or receiver module. The circuit in FIGS. 5A and B provides this feature for a single antenna, but the concept can be extended to multiple antennas for the receiver. For example, it may be desirable in some cases to display an RSTA trace from two or more antennas on the receiver display.

Another aspect of the invention is directed to the ability to separately identify the frequency band of the trace due to the receiver being tuned from the RF power due to other channels or other sources. For example, the trace for the frequency band of a given tuned receiver channel can be displayed in one color and the remainder of the trace can be displayed in another color. Further, it may be desirable that the receiver be programmed to enable the user to name the portion of the RTSA trace corresponding to the selected channel frequency band and also label the portion of the RTSA trace corresponding to the selected channel frequency band with the name when the trace is displayed.

The invention can also be implemented in order to allow the user to listen to the audio for the selected channel while at the same time displaying the RSTA trace for a given antenna. It may also be desirable to enable the receiver to determine audio level or receive audio level data from a stand-alone audio meter. The audio level can then be displayed contemporaneously with RTSA trace.

The invention can be implemented in a microphone receiver module having one or more wireless microphone receiving units that remain operative when attempting to continue receiving wireless information from corresponding microphone transmitter units. In order to properly communicate, a user may assign a unique RF band to each wireless microphone receiver transmitter pair such that each RF band will allow for a data rate that is sufficient to support the communicating of audio data. In one embodiment, multiple receiver units are integrated into one or more receiver modules. Rather than directly integrating the receiver modules into the mixer/recorder, a module may be kept separate where it may be either directly connected to the mixer/recorder module or when desired, placed at a nominal distance (usually in the direction of the transmitter units) and connected via a wired connector or a wireless connection to the mixer/recorder module. This connection between a receiver module and the mixer/recorder module may also be either wired or wireless Ethernet and the receiver module may process the audio information into a “Digital Audio through Ethernet” (DANTE) compatible format before transmitting it to the mixer/recorder module. A receiver module may collect and analyze information received from each transmitter unit to construct the best possible representation of information (audio waveform) originally detected and sent by the microphone elements. The resultant audio information or constructed waveform is supplied to one or more mixer/recorder endpoints (or a mixer/recorder module). This requires the information regarding the pairing of each wireless microphone receiver and transmitter and associated RF band to be determined at some point in preparation for use as part of a wireless microphone environment.

In some circumstances, operations performed by the receiver module may include dynamically selecting an RF band sent by the transmitter module that has the lowest error rate in its decoded audio signal. In other circumstances, it may select decoded information received by the receiver module reporting the highest signal strength from the microphone module. In yet other embodiments, the decoded information from multiple receiver modules may be blended together with decoded information from multiple receiver modules to produce a decoded signal that is higher quality than what would otherwise be possible from information received from a single receiver module. Based on this, the mixer/recorder module reconstructs (and may optionally output) electrical waveforms or data representative of the original audio signal.

This resultant output from the receiver module may then be recorded, broadcast, mixed with other audio sources and/or played back to listeners via headphone or loudspeaker arrangement. In some embodiments, the microphone transmitter modules themselves will encode audio waveform data to reduce bandwidth requirements. In these cases, the step of decoding the data for the actual audio waveform (audio PCM data) may be performed at either each receiver module, the mixer/recorder module or at a later time if this data is to be recorded.

The invention also contemplates systems using multiple receiver modules having the described RTSA feature built-in for its antennas. The receiver modules can be placed in a distributed manner on a set or on a stage, and the RTSA trace information can be shared among the other receiver modules or a central hub for display. This can be accomplished using Ethernet connections between the receiver modules. This aspect of the invention can be implemented for example in connection with the diversity receiver technique disclosed in U.S. Pat. No. 10,433,084, by Matt Anderson, entitled “Network System for Reliable Reception of Wireless Audio,” issuing on Oct. 1, 2019, which is hereby incorporated by reference.

Some novel aspects of the disclosed invention may be desirable in receivers that provide an RF scan feature instead of an RTSA trace as described. For example, the ability to separately identify the portion of an RF scan due to a receiver channel being tuned from the RF scan due to other channels or other sources is useful even without the use of an RTSA. The portion of the scan corresponding to the frequency band for a given tuned receiver channel can be displayed in one color and the remainder of the scan can be displayed in another color. Also, the receiver can be programmed to enable the user to name the portion of the RF scan corresponding to the selected channel frequency band and also label the portion of the RF scan corresponding to the selected channel frequency band with the name when the scan is displayed.

### BRIEF DESCRIPTION OF THE DRAWINGS

FIG. 1 is a simplified diagram showing a frontal view for an array of wireless receivers mounted side by side into a receiver module. This may be accomplished by constructing a rack-mounted system or alternatively a wireless receiver module wherein several receiver units may be slotted in or built together into a single unit. In this example, a total of four touch-screen control panel/displays are arranged side-by-side, one each for the four wireless microphone receivers contained in this module. The receiver module has two antennas in this example.

FIG. 2 shows an RTSA trace (zooming in to display better detail for a single display from the unit of FIG. 1) on a receiver display screen in accordance with the invention, where the refresh rate is increased to several times per second (e.g. 60 Hz).

FIG. 3 illustrates an RTSA trace on a display screen for a receiver module according to a preferred embodiment of the disclosed invention, where the portion of the trace for the frequency band of the receiver channel being tuned is depicted as the color yellow, and the remainder of the RF power spectrum is depicted as the color green.

FIG. 4 illustrates another example for an RTSA trace (zooming in to display better detail for a single display from the unit of FIG. 3) according to another exemplary embodiment of the disclosed invention that graphically indicates how the signal-to-noise-ratio (SNR) may be determined at a selected frequency.

FIGS. 5A and B are a block diagram illustrating various stages for a method of generating data for an RTSA trace to display on a receiver screen according to a preferred embodiment of the invention.

### DETAILED DESCRIPTION

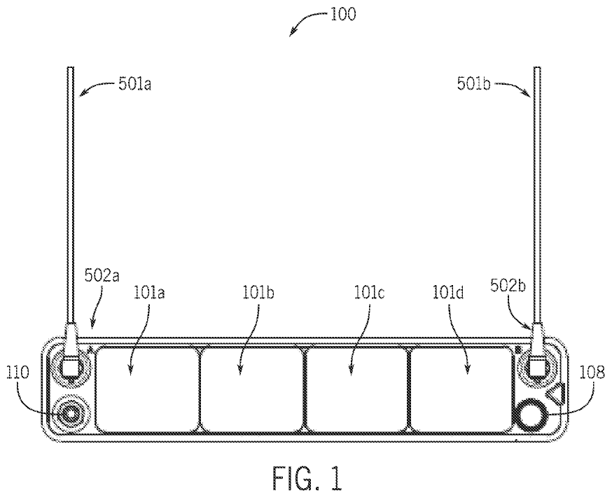

FIG. 1 shows a receiver module 100 with a series of 4 touchscreen displays 101a, 101b, 101c and 101d (where each is hereafter generically referred as a “touchscreen display” 101). The touchscreen displays 101a, 101b, 101c and 101d are located side-by-side to be conveniently accessible from the front side of the containing equipment chassis. In this example, each touchscreen display 101a, 101b, 101c and 101d may be assigned to a single stereo (2 channel) wireless microphone (for a total of 8 channels in this example). In this example, control and configuration for each receiver unit is accomplished from user input collected via a hierarchy of interactive nested control menus accessible from its touchscreen display 101a, 101b, 101c or 101d. This arrangement may be achieved either by a rack mount system where receiver units individually plug into mechanical slots provided in the rack system or by a microphone receiver module where the function for these displays 101 and associated wireless microphone receiver units are all built into a singular module 100. These touchscreen displays 101 may be programmed to serve both as a user interface for programming and/or configuring any given RTPUC and as an interactive display providing status, data and live information while in operation. In addition to the touch screen displays 101, this receiver module 100 has a control knob 108 and a headphone jack 110. The receiver module 100 also has antennas 501a, 501b, mounted on either side of the multi-channel receiver module 100. In the disclosed example, the antennas 501a, 501b serve to receive RF signals intended for any of the receiver units contained in the receiver module 100. While these are shown in a parallel configuration in FIG. 1, they may be attached such that they may be rotated (or swiveled) at their base 502a, 502b to point in any preferred direction. In many cases, orientating them in an orthogonal pattern (to receive RF signals of any polarity) may be preferable. It should be noted that the invention can be implemented on receiver modules having a single antenna, two antennas, or multiple antennas. In contrast to this example other embodiments may include those where touchscreen displays may be arranged (rather than in a single row) in multiple rows or a grid pattern.

The initial pairing of the receiver and the microphone transmitter in this embodiment is accomplished via a USB-c connection when the products are originally set up for use. Prior to pairing the receiver and the transmitter can communicate using a backlink, e.g., a 2.4 GHz frequency hopping communications (back) channel.

The modulation used for transmitting wireless audio data from the microphone transmitter may rely on FM, PSK, BPSK, QPSK, etc.) or spread-spectrum techniques. Other elements not shown that may be part of the design for the microphone transmitter module include a mechanical housing for structural support, various circuits, power supplies, batteries, adapters, clips, amplifiers, companders, limiters, signal conditioners or filters, analog to digital converters, communications circuits, modulators, antennas, microprocessor, digital signal processors and/or software for configuration, control and operation of the microphone module that will be apparent to one skilled in the art.

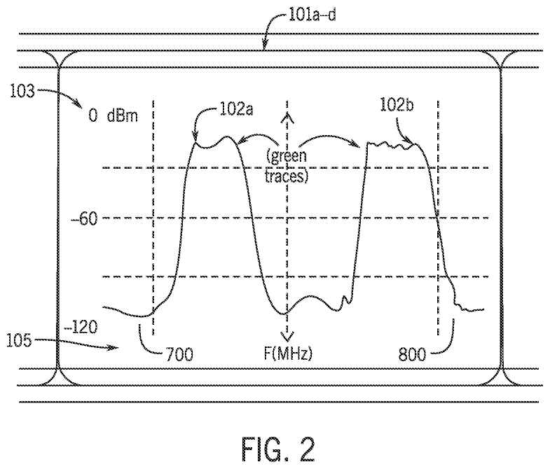

FIG. 2 illustrates an expanded view of one of the touchscreen displays 101a-d, where according to the invention, a user enters commands to provide an RTSA trace 102a, 102b on the display screen 101 and allow the user to better understand the RF environment in which the RTPUC is to operate. As shown in this example, a single color trace 102a, 102b may be used to provide RTSA information. In this embodiment, the height of the trace 102a, 102b indicates the power level in dBm as referenced to the y-axis scale 103. The position along the x-axis is referenced with respect to the labeled frequency in MHz, see reference number 105 (where in this example, the x-axis spans from 700 MHz to 800 MHz). In some embodiments, a user may smoothly swipe their finger to the left or right along the touch screen to cause the displayed frequency range to scroll to a higher or lower range, respectively. Further embodiments envisioned by this disclosure include those whereby using two fingers at the same time on the touch screen 101 and either drawing them closer together or further apart, the user may compress or expand, respectively, the displayed frequency range until a desired range is displayed on the touch screen. As shown, two peaks in the RF spectrum are illustrated present for this example. The first peak 102a (on the left side) may be assumed present due to the information being transmitted to and intended for the receiver portion of the RTPUC. However, since the RTPUC does not operate in isolation, other RF information may be present such as that creating the second peak 102b (assumed originating from a neighboring transmitter unit).

In the exemplary embodiment, the user turns the control knob 108 (FIG. 1) with the receiver 100 in RTSA mode to move a vertical frequency marker to a clean frequency (i.e., where there is low background RF noise). The user then presses the control knob 108 to display a list of receiver channels and selects the appropriate channel to assign the clean frequency. The frequency is automatically pushed to the transmitter and its RF signal appears in the trace. Alternatively, touchscreen controls can be used to select a clean frequency and assign it to a given receiver channel. Further, it is possible to select an auto assign function to automatically deploy clean frequencies to all active channels, as described later in this application. As used herein, means for configuring the receiver and a paired microphone transmitter to a selected channel frequency band includes both the manual selection using a control knob or touchscreen controls, or equivalents, as described above and also the auto assign feature described later in this disclosure.

With the embodiment illustrated in FIG. 2, the user attempting to set up an RTPUC with a suitable RF operating band might not always be able to identify which peak 102a or 102b is from the wireless transmitter receiver pair being tuned. In other words, the user may be tempted to assume that the frequency region occupied by the higher energy region due to the first peak 102a is not available, when it is in fact due to the RTPUC of interest. This problem of identifying relevant portions of the RF power spectrum occurs with prior art receivers implementing a scan function. It should be apparent at this point that even in cases where a wireless microphone receiver module is equipped with an RTSA, confusion may arise as to the origin of RF power peaks shown on the touchscreen display.

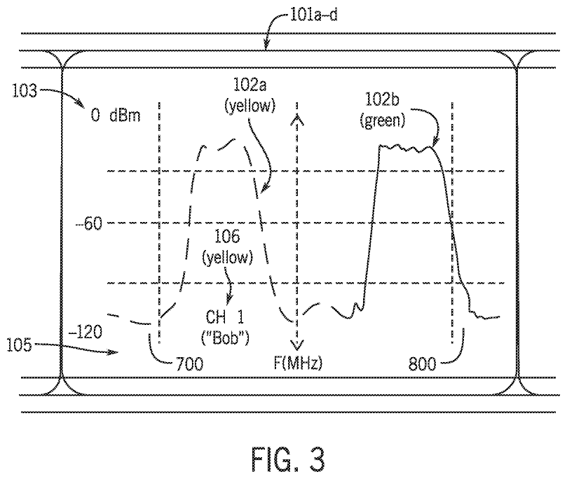

The embodiment of the invention described in FIG. 3 addresses the difficulties described above by providing a color-coded RTSA trace. Referring to FIG. 3, the color-coded RTSA trace allows the user to understand the RF field strength at the antenna while at the same time indicating what source the displayed RF signal energy originates from. As can be seen in FIG. 3, the RF signal energy associated with the RTPUC is differentiated from RF signal energy being received by the antenna from other transmitters (or for that matter by any other nearby devices) by color coding. The portion of the trace for the RF spectrum associated with the receiver under configuration with an alternate color (represented by dashed portion of the trace labeled 102a)—in this example yellow rather than green (represented by solid portion of the trace labeled 102b) that is used for the RF spectra due to equipment other than the RTPUC. The modulation bandwidth and programmed modulator frequency of the RTPUC are supplied by the user to the receiver/transmitter pair and are known by the receiver. The receiver in turn color codes the identified range on the RTSA trace to indicate that the identified frequency range is in use by the receiver channel and its paired transmitter. This concept is easily extended to cases where several sources are to be indicated, with additional colors (e.g., blue, red, white, etc.) that may be applied over different frequency spans of the trace as appropriate. In alternative embodiments, line type (such as dashed, varied thickness or brightness) rather than color may be used to indicate the RF source, as could other indicators, such as shading below portions of the graph. In some embodiments, flashing segments or time varying brightness or thickness could also indicate the RF source.

Still referring to the embodiment shown in FIG. 3, the receiver may be programmed to enable the user to name and label the portion of the RTSA trace 102a corresponding to a selected channel frequency band. For example, in FIG. 3, Channel 1 if a user chooses to assign the name “Bob” to represent the content of Ch 1, the label 106 ‘Ch 1 (“Bob”)’ may be displayed to further identify the portion of the RTSA trace corresponding to the selected channel frequency band.

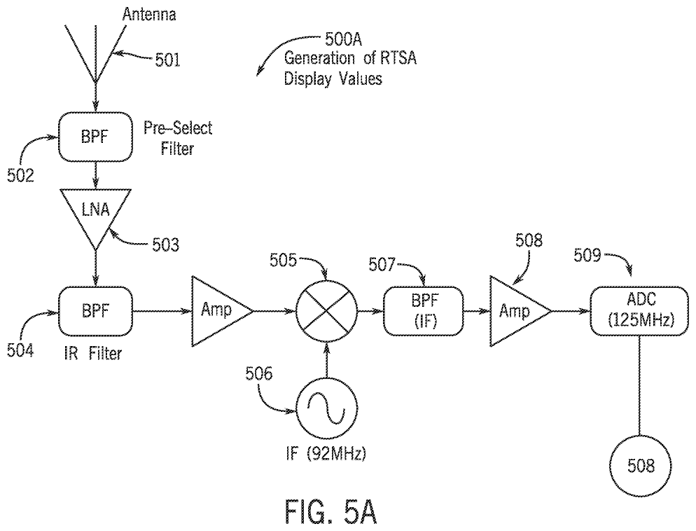

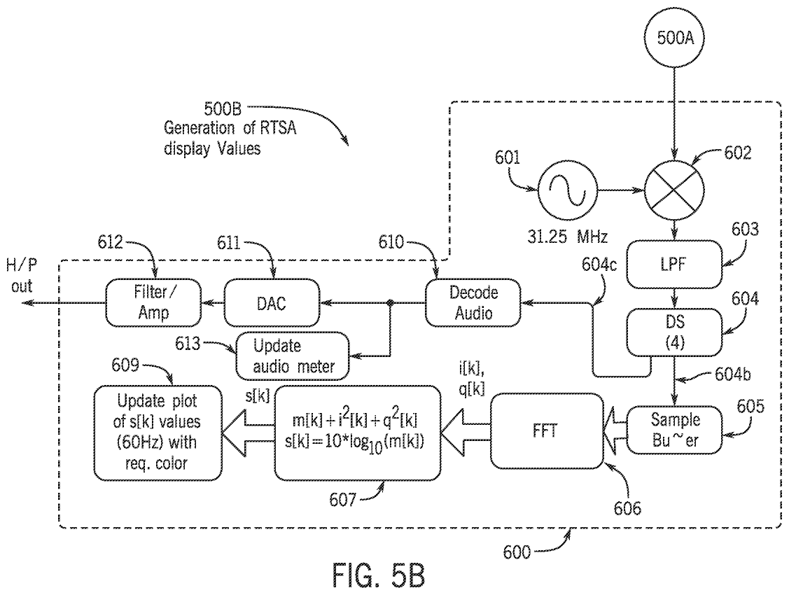

FIGS. 5A and 5B are a detailed block diagram of a circuit 500 that is able to perform the functions of a real time spectrum analyzer (RTSA) and can also be integrated into a receiver, a multi-channel receiver, or other equipment associated with receiver such mixer-recorder with an integrated multi-channel receiver. Referring to FIG. 5A, the RTSA circuit 500 generates data representing the power spectrum for an input signal from an antenna which can then be displayed as an RTSA trace. In this embodiment, the RF input signal to be characterized is received by an antenna (or antenna pair) 501 (a physical depiction of the antennas is also referenced by 501a, b in FIG. 1). Immediately after a signal is picked up by the antenna 501, a preselection bandpass filter 502 is applied in order to reduce out of band signal energy as well as partially reject image band signals. The preselection filter 502 is an analog filter which in this exemplary embodiment allows signal frequencies corresponding to those in an allowed transmission channel having a bandwidth of 24 MHz to pass. The resultant signal is then amplified by a low noise amplifier or LNA 503. This low noise amplification suppresses the relative contribution of noise by the succeeding stages. Following the LNA 503, the resultant amplified signal is applied as input to an image rejection (IR) filter 504, which is another analog bandpass filter. The LNA 504 in this exemplary embodiment allows signal frequencies corresponding to a single 24 MHz bandwidth channel in the range between 470 MHz and 1525 MHz to pass Then again, an amplifier is used to bring the signal level up to a suitable level for a mixer 505. The mixer is applied to down-convert the signal from the RF frequency to an intermediate frequency (IF) using the output of a local oscillator 506 set to the intermediate frequency of e.g. 92 MHz. The output of the mixer 505 is then applied as the input to another IF filter 507 (analog bandpass filter) and again amplified using another amplifier 508 such that the signal levels are appropriate (typically a few volts) to be supplied as input to an analog to digital converter (ADC) 509 that may operate at, e.g., 125 MHz.

Referring to FIG. 5B, after the ADC 509 has converted the input signal to a series of digital samples, the digital samples are supplied as the input to an FPGA 600. It should be noted that elements of FIG. 5B that lie inside the block enclosure labeled FGPA 600 are to be considered as implemented within the FGPA 600, while those elements outside this block are external to it and may in some cases be analog. Alternative embodiments apparent to one skilled in the art may include those where a high-speed DSP is used in place of the FPGA 600 to produce similar functions or in other cases, multiple FPGA units may work together to mimic those described in this disclosure. As the digital data is received by the FPGA 600, it is further down converted by the internal mixer 602 using a base frequency of 31.25 MHz, see local oscillator 601. This data may be filtered by a low-pass-filter (LFP) 603 to remove images prior to down-sampling (in this example by a ratio of 4 to 1) at the down-sampler 604 to produce a 31.25 MHz digital signal output 604b. Once down sampled, the data 604b is streamed into a digital buffer 605 where sufficient storage is present for collecting up to 4096 samples. At intervals when the digital buffer 605 is fully refreshed (immediately after use of prior stored data), these samples are supplied as input to a fast Fourier transform (FFT) 606, producing a frequency domain representation of the data of size equal to that for the input buffer 605. The resultant frequency domain samples are further processed through math block 607, where first the square of the magnitude, m² [k], for each frequency domain point is calculated by the sum of squares for the real, i[k], and complex portion, q[k], of each sample by summing their squares. Finally, the magnitude values, m[k], are converted into decibels (using the equation, s[k]=10*log₁₀ (m²[k]). The FPGA 600 then supplies these decibel values to the touchscreen display for producing a color-coded trace 102 (after appropriate scaling) and if desired other information to be viewed on screen by the user such as illustrated in FIG. 2, 3 or 4. Block 609 in FIG. 5B indicates that the refresh rate in this example is 60 Hz. Block 609 also indicates that the various portions of the trace are associated with assigned colors at this step in the process. While the method disclosed here relies on an FFT applied to a data buffer, it should be apparent to those skilled in the art that alternative methods are anticipated for generating the decibel data, s[k]. For example, in some embodiments, the FFT of an autocorrelation sequence may provide suitable information for generating an RTSA trace.

Another stream of down sampled data 604c from the down sampler 604 can be used to produce audio so that a user can listen to the channel while the frequency and bandwidth are being adjusted and/or the RTSA trace is being displayed. This alternate stream of down sampled data 604c is decoded to produce digital audio data, e.g., PCM data, see block 610. Then, in FIG. 5B, the digital audio data is converted to an analog signal, block 611, and filtered and amplified, block 612. The amplified analog signal is provided to a headphone jack 110 so the user can use headphones to listen to audio at the same time that the user is viewing the RTSA traces, and possibly adjusting channel frequency and/or bandwidth.

Still referring to FIG. 5B, it may also be desirable to enable the receiver to determine audio level or receive audio level data from an audio meter. In this way, the audio level can then be displayed contemporaneously with RTSA trace 102a, 102b. In FIG. 5B, decoded audio data, block 610, can be used to update audio level and simulate real time audio level data, which can be displayed along with the RTSA trace. Alternatively, the receiver or receiver module can have a data port able to receive data from a stand-alone audio meter.

In yet other embodiments, a bidirectional communication link may be constructed between each wireless microphone receiver and its paired wireless microphone transmitter. This capability for the receiver to send data back to the transmitter is sometimes referred to the art as “backlink”. In these cases, embodiments are envisioned whereby a receiver could notify its paired transmitter (via backlink) to stop transmitting for a specified period of time. This would provide a temporal window of opportunity for the receiver to measure RF levels without the influence of its communication over an RF band.

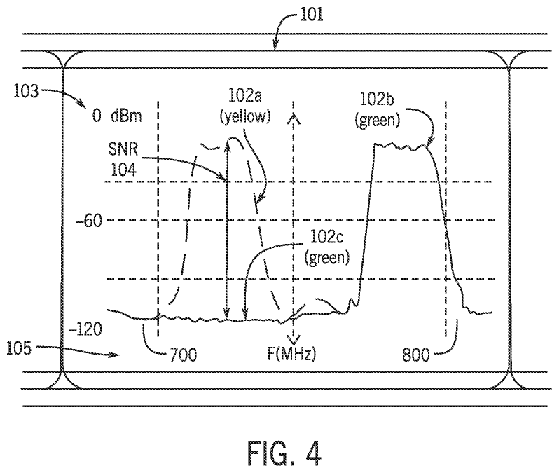

For example, in embodiments where a backlink is built into the hardware, the receiver for an RTPUC may instruct its paired transmitter to cease RF broadcasting for a predetermined period of time during which the receiver will have the opportunity to measure the RTSA trace for the combination of all devices present, except for its specified paired transmitter. This RTSA trace information is stored and presented on the RTSA touchscreen display 101 as shown in FIG. 4, along with a live RTSA trace during which the transmitter of the RTPUC is transmitting. In FIG. 4, another the green trace 102c represents the RF levels due to all devices except the RTPUC paired transmitter. This has the advantage of letting the user know more clearly what influence the collection of all the other devices are having specifically over the prospective band for the RTPUC. In some embodiments, the software may be configured to display the RF spectrum as a single color (as shown as green, in FIG. 4, see line sections 102a and 102c) when with the RF spectrum over the desired bandwidth of the transmitter paired with the RTPUC as a different color (yellow in the case of FIG. 4, see line section 102b). Alternatively, some users may prefer to set the color the line segment 102c to a third color for easy identification (e.g., blue) to indicate that its measurement took place without the influence of the paired transmitter.

Further modifications are envisioned as well. For example, where based on stored RF levels taken without and then with an RTPUC active, a measure of the signal to noise ratio (SNR) for this RTPUC may be inferred from the distance in the dB domain between these measurements, see reference number 104 as shown in FIG. 4. In some embodiments, the trace for RF level both with and without the RTPUC active may be displayed, whereas in others, users may prefer to view only the SNR, as derived from these measurements 102a, 102b and 102c stored in the receiver. In yet other embodiments, it may be preferable to program the system to allow the user to drag the SNR indicator line 104 left or right along the frequency axis, while displaying a numerical value for its length in dB at the positioned frequency.

Once the user powers up the units, the user can pick preferred frequency bands as explained previously. Also, it may be desirable to automatically scan for an optimal band(s). For example, receivers communicate with the transmitters to turn off transmission and then enable the transmitter to turn on one band at a time. This way the system can measure and choose the band with the best SNR characteristics for each RTPUC.

### CONCLUSION

The construction and arrangement of the elements of the systems and methods as shown in the exemplary (and alternative) embodiments are illustrative only. Although only a few embodiments of the present disclosure have been described in detail,

Given the preceding disclosure, those skilled in the art will readily appreciate that many modifications are possible (e.g., variations in sizes, dimensions, structures, shapes and proportions of RTSA touchscreen display or the simultaneous presentation of parameters, or other modifications involving the arrangement, use of materials, colors, orientations, etc. for information provided) without materially departing from the novel teachings and advantages of the subject matter disclosed.

Also, as noted earlier, the invention can be implemented on a stand-alone receiver with a screen capable of displaying an RTSA trace, and can be also applied to multiple receivers integrated into a receiver module or into other equipment such as a mixer-recorder. Several stand-alone receivers implementing the invention can be mounted in racks or can be distributed on the stage or set. In one particular advantageous embodiment, the several multi-receiver modules are dispersed at different locations on a stage or set, and each of the receivers implements the ability to generate and display RTSA traces as described herein. Desirably, the several multi-receiver modules are connected to one another, e.g., via an Ethernet connection, and the various RTSA traces can be viewed on the screens for the other receivers, or a hub or a computer connected to the system. In addition, as mentioned, the circuit in FIGS. 5A and B can be duplicated to provide an RTSA trace for additional antennas on a given receiver or receiver module. Alternatively, multiple antenna signals available for a given receiver channel can be combined prior to inputting the circuit of FIGS. 5A and B if it is desired to determine an RTSA trace for the composite antenna output.

1. A wireless receiver or receiver module in a sound recording system, comprising:
at least one antenna that receives RF signals over a wide frequency range and outputs an antenna signal;
and
a real-time spectrum analyzer (RTSA) in the receiver or receiver module that generates an RTSA trace from the antenna signal;
wherein the RTSA trace is displayed in real time for the user view.

2. The wireless receiver or receiver module according to claim 1 wherein the receiver or receiver module further comprises a touch screen and the RTSA trace is displayed on the touch screen.

3. The wireless receiver or receiver module according to claim 1 wherein the RTSA comprises an analog circuit that receives the antenna signal and filters, amplifies and down coverts the analog signal, an analog-to-digital converter that receives the analog signal from the analog circuit and outputs a digital input signal, and a processor that receives the digital input signal and outputs values representing decibels for a given frequency.

4. The wireless receiver or receiver module according to claim 3 wherein the processor comprises one or more field programmable gate arrays.

5. The wireless receiver or receiver module according to claim 4 wherein one or more field programmable gate arrays are programmed to comprise a sample buffer, a Fast Fourier Transform, and means for calculating decibel levels from the output of the Fast Fourier Transform.

6. The wireless receiver or receiver module according to claim 1 wherein the portion of the RTSA trace corresponding to the selected channel frequency band is displayed to be distinct from the remainder of the RTSA trace.

7. The wireless receiver or receiver module according to claim 1 wherein the portion of the RTSA trace corresponding to the selected channel frequency band is displayed in a color distinct from the color of the remainder of the RTSA trace.

8. The wireless receiver or receiver module according to claim 6 comprising means to name the portion of the RTSA trace corresponding to the selected channel frequency band and label the portion of the RTSA trace corresponding to the selected channel frequency band with the name when displayed.

9. The wireless receiver or receiver module according to claim 1 further comprising a backlink communication connection to a paired microphone transmitter, wherein the paired microphone transmitter receives a command from the receiver over the backlink communication connection to turn off the paired microphone transmitter for a preselected period of time, and the RTSA is used to determine the SNR for the selected channel by comparing RF energy levels when the transmitter is off to when the transmitter is on.

10. The wireless receiver or receiver module according to claim 1 further comprising another antenna and another RTSA, wherein the RTSA trace for either or both antenna is displayed.

11. The wireless receiver or receiver module according to claim 1 further comprising several additional antennas and several addition RTSAs, wherein the RTSA trace for any and all of the antennas can be displayed.

12. The wireless receiver or receiver module according to claim 1 wherein the receiver or receiver module also includes an audio output port to enable a user to listen to a given channel while viewing an RTSA trace.

13. The wireless receiver or receiver module according to claim 1 wherein the receiver also includes means for receiving audio level input from an audio meter wherein the audio level is displayed simultaneously with the RTSA trace for the user view.

14. The wireless receiver or receiver module according to claim 1 wherein the receiver also includes means for determining audio level from the antenna signal, wherein the audio level is displayed simultaneously with the RTSA trace for the user view.

15. A system including multiple wireless receivers or receiver modules according to claim 1, and each receiver or receiver module is connected to the other receivers or receiver modules or to a hub or a computer via an Ethernet connection, thereby enabling the RTSA traces generated by one of the receivers or receiver modules to viewed on another device.

16. The wireless receiver or receiver module according to claim 1 further comprising means for configuring the receiver and a paired microphone transmitter over to a selected channel frequency band, wherein the RF signals being received by the antenna over the wide frequency range include audio data transmitted from the paired microphone transmitter via an RF signal in the selected channel frequency band.

17. A wireless receiver or receiver module in a sound recording system, comprising:
at least one antenna that receives RF signals over a wide frequency range and outputs an antenna signal;
a display screen;
means for configuring the receiver and a paired microphone transmitter to a selected channel frequency band, wherein the RF signals being received by the antenna over the wide frequency range include audio data transmitted from the paired microphone transmitter via an RF signal in the selected channel frequency band; and
means in the receiver or receiver module for generating a plot of RF power versus frequency from the antenna signal and displaying the plot on the display screen;
wherein the portion of the plot corresponding to the selected channel frequency band is displayed to be distinct from the remainder of the plot.

18. The wireless receiver or receiver module according to claim 17, wherein the portion of the plot corresponding to the selected channel frequency band is displayed in a color distinct from the color of the remainder of the plot.

19. The wireless receiver or receiver module according to claim 17 comprising means to name the portion of the plot corresponding to the selected channel frequency band and label the portion of the plot corresponding to the selected channel frequency band with the name when displayed.

20. The wireless receiver or receiver module according to claim 17 said means in the receiver or receiver module for generating a plot of RF power versus frequency from the antenna signal and displaying the plot on the display screen comprises a frequency scan circuit.

21. The wireless receiver or receiver module according to claim 17 said means in the receiver or receiver module for generating a plot of RF power versus frequency from the antenna signal and displaying the plot on the display screen comprises a real-time spectrum analyzer (RTSA) in the receiver or receiver module that generates an RTSA trace from the antenna signal.
